(19) United States
(12) Patent Application Publication
(10) Pub. No.: US 2012/0218038 A1
(43) Pub. Date: Aug. 30, 2012

(54) AUTOMATIC GAIN CONTROL DEVICE HAVING FREQUENCY RESPONSE UNIT INCLUDED THEREIN AND RELATED AUTOMATIC GAIN CONTROL METHOD THEREOF

(76) Inventors: Hsien-Cheng Chen, Hsinchu County (TW); Ying-Chung Chiu, Hsinchu County (TW)

(21) Appl. No.: 13/337,300

(22) Filed: Dec. 27, 2011

(30) Foreign Application Priority Data
Feb. 25, 2011 (TW) 100106384

(51) Int. Cl. H03G 3/20

(52) U.S. Cl. 330/127

(57) ABSTRACT

An automatic gain control device includes a variable-gain amplifier, a power detector, a gain control unit and a frequency response unit. The variable-gain amplifier is implemented for determining a gain according to a gain control signal and generating an amplified signal by amplifying a received signal according to the gain. The power detector is implemented for determining a power of a frequency response result and accordingly outputting a detection result. The gain control unit is implemented for outputting the gain control signal according to the detection result. The frequency response unit is implemented for performing a frequency response operation on the amplified signal to generate the frequency response result.

### BACKGROUND OF THE INVENTION

1. Field of the Invention

The present invention relates to a method and device of automatic gain control, and more particularly, to a method and device of automatic gain control capable of properly adjusting the gain according to characteristics of an interference signal.

2. Description of the Prior Art

Automatic Gain Control (AGC) device is a commonly-used electronic device in signal processing, and used for automatically regulating an input amplitude to make it fall within an appropriate range, thus maintaining an output voltage within a certain voltage range to ensure that a back-end circuit functions correctly.

Please refer to FIG. 1, which is a functional block diagram of a prior art automatic gain control device 10. The automatic gain control device 10 includes a variable-gain amplifier 100, a filter 102, a power detector 104 and a gain control unit 106. Operations of the automatic gain control device 10 are narrated as follows. First, the variable-gain amplifier 100 amplifies a received signal Si according to a predetermined gain, and generates an amplified signal Sa. The amplified signal Sa is then turned into an output signal So by undergoing a filtering operation performed via the filter 102 to filter out out-of-band signals or noise interference. The output signal So is provided to the back-end circuit for follow-up operations. The amplified signal Sa is further used in a feedback control of a gain of the variable-gain amplifier 100. The feedback control is accomplished by the power detector 104 which detects power of the amplified signal Sa and the gain control unit 106 which outputs a gain control signal Gain_CMD to the variable-gain amplifier 100 according to a detection result RST of the power detector 104 to thereby adjust the gain of the variable-gain amplifier 100.

To put it simply, the operation of the automatic gain control device 10 can be divided into two parts: one is for signal processing, formed by the variable-gain amplifier 100 and the filter 102 (i.e., the Si→Sa→So signal path); the other is for the feedback control or gain control, formed by the variable-gain amplifier 100, the power detector 104 and the gain control unit 106 (i.e., the Si→RST→Gain_CMD signal path).

In the signal processing part of the automatic gain control device 10, the filter 102 is mainly utilized for filtering out interference signals to prevent operations of the back-end circuit from being affected by the interference signals. In addition, since the amplified signal Sa comprises amplified interference signals, the power detector 104 may be affected by the amplified interference signals when detecting the power of the amplified signal Sa, resulting in faulty judgments of the gain control unit 106.

In detail, please refer to FIG. 2 to FIG. 4. FIG. 2 is a schematic diagram of the amplified signal Sa and output signal So corresponding to the received signal Si having no interference signal included therein. FIG. 3 is a schematic diagram of the amplified signal Sa and output signal So corresponding to the received signal Si having an interference signal with a frequency nearer to that of the received signal Si. FIG. 4 is a schematic diagram of the amplified signal Sa and output signal So corresponding to the received signal Si having an interference signal with a frequency farther from that of the received signal Si. Assume that a desired signal Snd is in the received signal Si, and a frequency band thereof is in between frequencies f1 and f2, as shown in FIG. 2. When the received signal Si is interference-free, i.e. the received signal Si solely consists of the wanted signal Snd, the variable-gain amplifier 100 amplifies the received signal Si moderately, and then the filter 102 performs the filtering operation upon an output of the variable-gain amplifier 100. On the contrary, when the received signal Si includes the undesired interference signal Sinf, and a frequency band of the interference signal Sinf is in between frequencies f2 and f3, as shown in FIG. 3, the output signal So contains a modulation result of the interference signal Sinf (i.e., an interference modulation signal IMS1, as shown in the shaded area) after processed by the variable-gain amplifier 100 and the filter 102. Similarly, if a frequency band of the interference signal Sinf is in between frequencies f3 and f4, as shown in FIG. 4, the output signal So contains an interference modulation signal IMS2 after processed by the variable-gain amplifier 100 and the filter 102. When the gain control unit 106 determines the gain of the variable-gain amplifier 100, the interference modulation signals IMS1 and IMS2 need to be constrained under a predetermined value, so as to achieve best signal reception quality. The interference modulation signal IMS1 is smaller than the interference modulation signal IMS2. In other words, when the undesired interference signal Sinf is farther from the wanted signal Snd, the gain control unit 106 controls the variable-gain amplifier 100 to amplify the received signal Si according to a higher gain; on the contrary, when the undesired interference signal Sinf is nearer to the wanted signal Snd, the gain control unit 106 controls the variable-gain amplifier 100 to amplify the received signal Si according to a lower gain.

However, in practice, owing to a wide-band characteristic of the power detector 104, the detection results RST are approximately the same. That is to say, no matter whether the interference signals are present or not, the detection results RST are approximately the same. Under the circumstances, the gain control unit 106 cannot control the variable-gain amplifier 100 to perform amplification operation with different gains in response to different frequency offsets of the interference signals (i.e., different frequency differences between the frequencies of the interference signals and the frequency of the wanted signal). To put it another way, above-mentioned examples in FIG. 2 to FIG. 4 all have the same gain.

As mentioned above, the gain control unit 106 cannot control the gain of the variable-gain amplifier 100 according to the frequencies of the interference signals, causing that the prior art automatic gain control device 10 can not achieve the best signal reception quality. In order to overcome this shortcoming, the prior art design usually determines a frequency band of an interference signal using a digital signal processing (DSP) means, which inevitably requires more circuit hierarchy and thus increases circuitry complexity, circuit area and signal lock-time significantly.

In short, the prior art design cannot handle the interference signals according to respective different frequency offsets to achieve optimized signal reception, and using the conventional DSP would lead to degraded performance and higher production cost. Therefore, the prior art design still has room for improvement.

### SUMMARY OF THE INVENTION

One of the objectives of the present invention is therefore to provide a method and device of automatic gain control.

According to one aspect of the present invention, an exemplary automatic gain control device is disclosed. The exemplary automatic gain control device includes a variable-gain amplifier, a power detector, a gain control unit and a frequency response unit. The variable-gain amplifier is for determining a gain according to a gain control signal and generating an amplified signal by amplifying a received signal according to the gain. The power detector is for determining a power of a frequency response result and accordingly outputting a detection result. The gain control unit is for outputting the gain control signal according to the detection result. The frequency response unit is for performing a frequency response operation on the amplified signal to generate the frequency response result.

According to another aspect of the present invention, an exemplary automatic gain control method is disclosed. The exemplary automatic gain control method includes: generating an amplified signal by amplifying a received signal according to a gain; performing a frequency response operation on the amplified signal to generate a frequency response result; and adjusting the gain according to the frequency response result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a prior art automatic gain control device.

FIG. 2 is a schematic diagram of an amplified signal and an output signal corresponding to a received signal having no interference signal included therein.

FIG. 3 is a schematic diagram of an amplified signal and an output signal corresponding to a received signal having an interference signal with a frequency nearer to that of the received signal.

FIG. 4 is a schematic diagram of an amplified signal and an output signal corresponding to a received signal having an interference signal with a frequency farther from that of the received signal.

FIG. 5 is a functional block diagram of an automatic gain control device according to an embodiment of the present invention.

FIG. 6 is a schematic diagram of a frequency response of a frequency response unit in FIG. 5 that has a frequency response of a band-pass filter.

FIG. 7 is a schematic diagram of an automatic gain control process according to an embodiment of the present invention.

### DETAILED DESCRIPTION

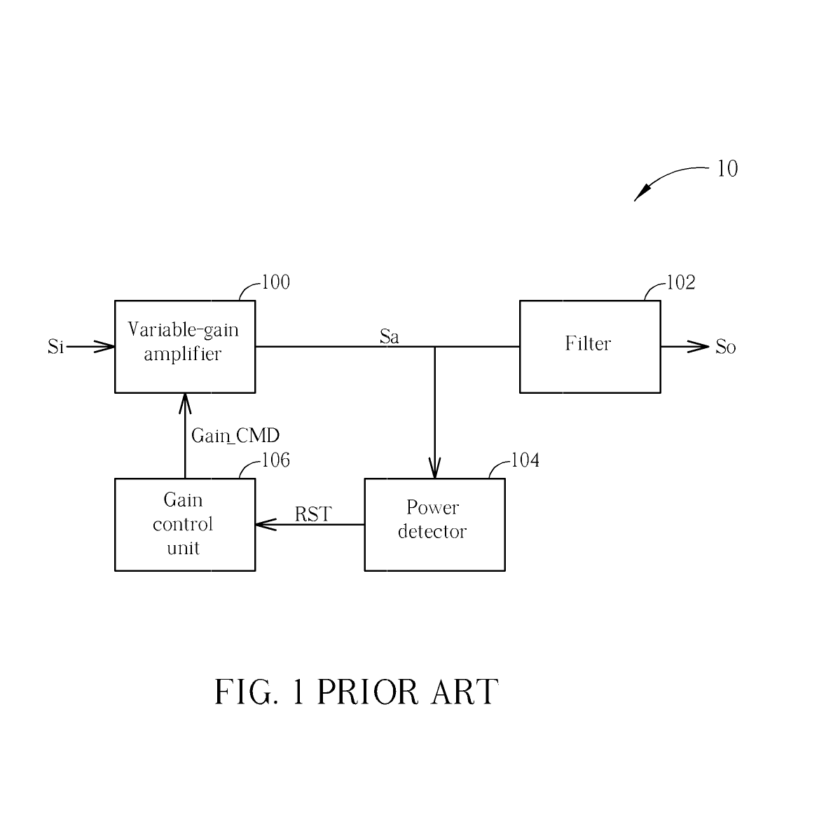

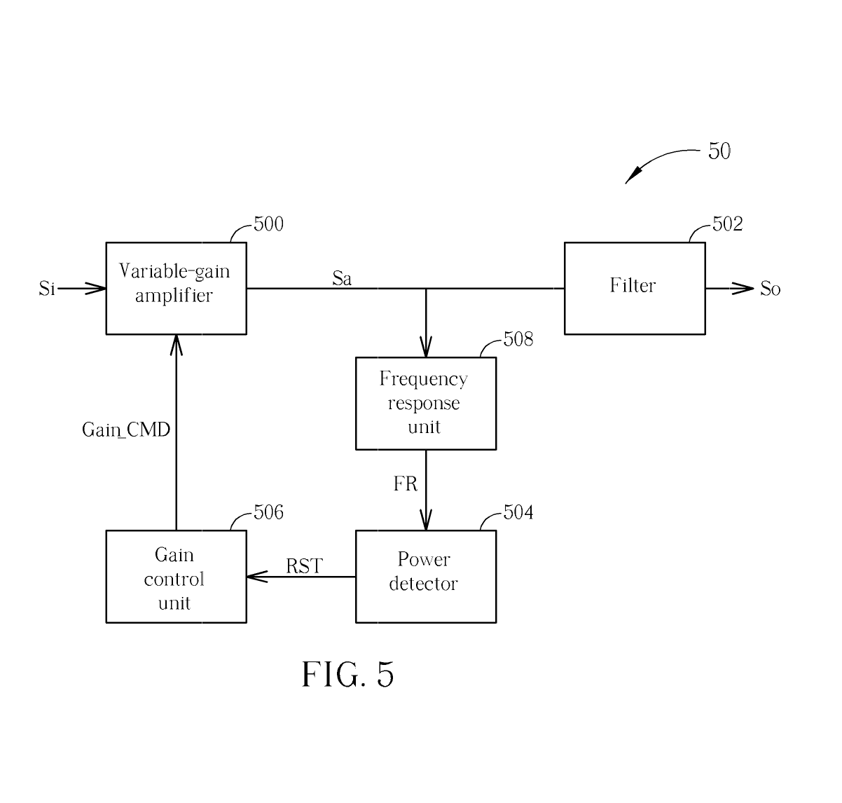

Please refer to FIG. 5, which is a functional block diagram of an automatic gain control device 50 according to an embodiment of the present invention. The automatic gain control device 50 includes a variable-gain amplifier 500, a filter 502, a power detector 504, a gain control unit 506 and a frequency response unit 508. As derived from comparing FIG. 1 with FIG. 5, except for the frequency response unit 508, the rest of the automatic gain control device 50 is almost identical to the automatic gain control device 10 in FIG. 1. It is therefore to adopt some of the symbols shown in FIG. 1 for simplicity. In detail, the signal processing part of the automatic gain control device 50 remains the same as the signal processing part of the automatic gain control device 10, whereas the gain control part of the automatic gain control device 50 has the frequency response unit 508 added thereto. The frequency response unit 508 is utilized for performing a frequency response operation on the amplified signal Sa output by the variable-gain amplifier 500, and accordingly generates a frequency response result FR. That is, the amplitude of the amplified signal Sa would be changed in response to frequency variation.

Therefore, the operational principle of the automatic gain control device 50 is narrated as follows. First, the variable-gain amplifier 500 amplifies a received signal Si according to a predetermined gain, and generates an amplified signal Sa. The amplified signal Sa is then turned into an output signal So by undergoing a filtering operation performed thereon via the filter 502 to filter out out-of-band signals and interferences. The output signal So is provided to the back-end circuit for follow-up operations. In addition, the frequency response unit 508 performs a frequency response operation on the amplified signal Sa to modify an amplitude of the amplified signal Sa, and output a corresponding frequency response result FR to the power detector 504. Next, the power detector 504 determines power of the frequency response result FR and accordingly outputs a detection result RST to the gain control unit 506, such that the gain control unit 506 outputs a gain control signal Gain_CMD to the variable-gain amplifier 500 to control the gain of the variable-gain amplifier 500.

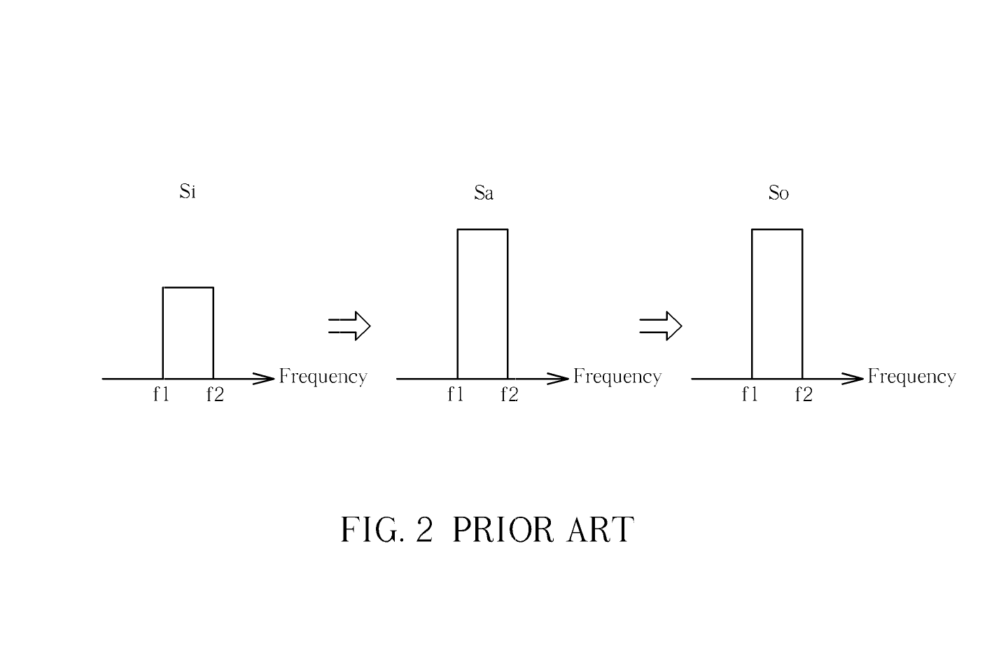

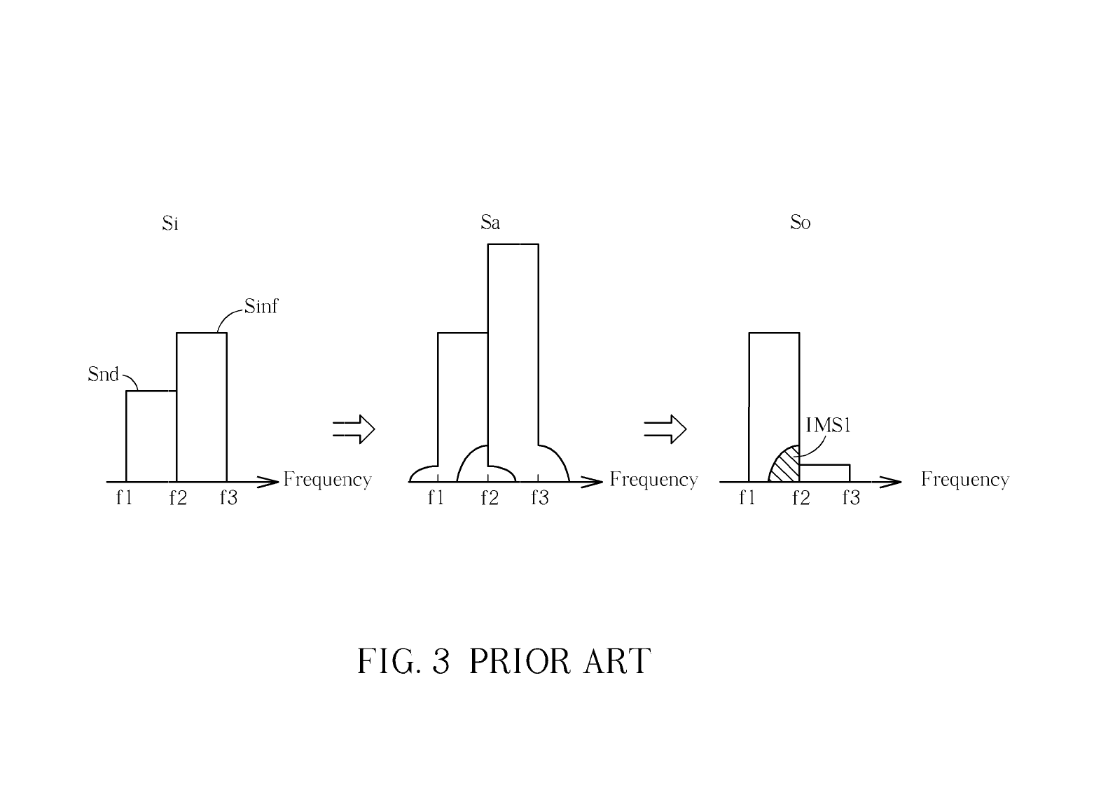

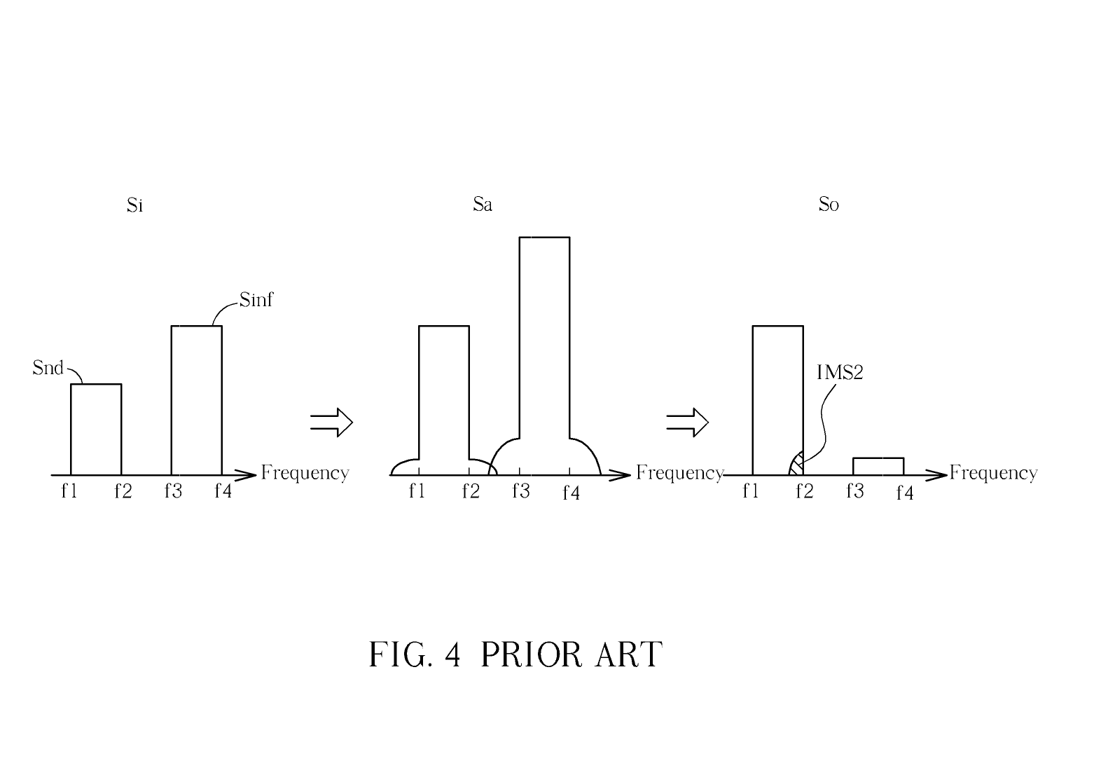

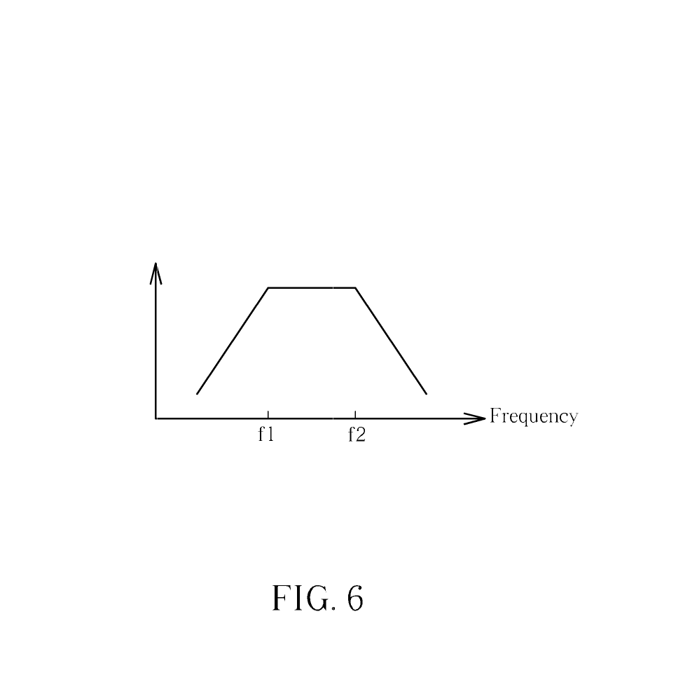

To put it simply, in the automatic gain control device 50, the power detector 504 determines the power of the frequency response result FR of the amplified signal Sa rather than the power of the amplified signal Sa itself. In other words, as long as the operation of the frequency response unit 508 is properly adjusted, the detection result RST of the power detector 504 can adequately reflect the frequency offsets of the interference signals. For instance, continuing to use FIG. 2 to FIG. 4 as examples, if a desired frequency band of the automatic gain control device 50 is in between frequencies f1 and f2 as shown in FIG. 6, the frequency response unit 508 is a band-pass filter and the pass band thereof is in between frequencies f1 and f2. In this way, the interference signals nearer to f1-f2 frequency band affect the detection result RST more, and the gain control unit 506 accordingly adjusts the gain of the variable-gain amplifier 500 such that the variable-gain amplifier 500 amplifies the received signal Si according to different gains to thereby achieve the best performance. That is to say, when the automatic gain control device 50 of the present invention receives the received signals Si shown in FIG. 2 to FIG. 4 respectively, the automatic gain control device 50 employs the highest gain in the case shown in FIG. 2, employs the lowest gain in the case shown in FIG. 3, and employs a mediate gain between the highest gain and the lowest gain in the case shown in FIG. 4.

Note that, FIG. 6 merely shows one example of possible frequency responses of the frequency response unit 508, and the frequency response of the frequency response unit 508 is not meant to this. The logic behind the operation of the frequency response unit 508 is associated with the frequency band to be attenuated. Therefore, based on the system requirement, the designer should implement the frequency response unit 508 by various circuits each capable of adjusting the gain in response to the frequency variation, such as high-pass filter(s), low-pass filter(s), narrow-band amplifier(s), etc.

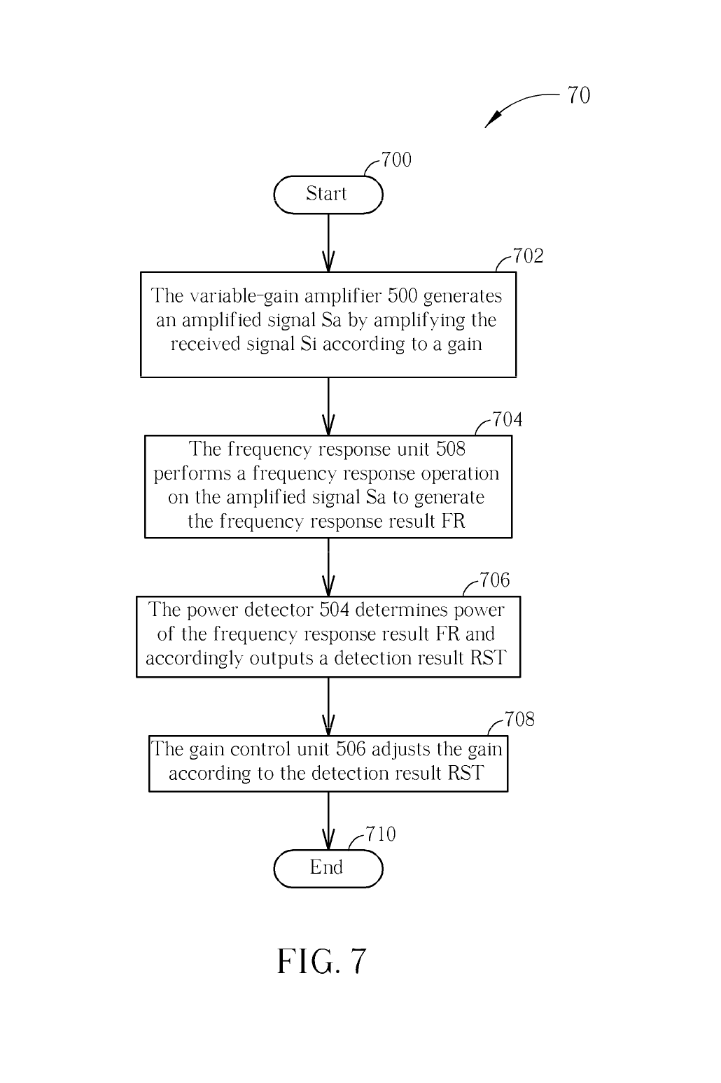

The operation of the gain control part of the automatic gain control device 50 can be further summarized into an automatic gain control process 70, as shown in FIG. 7. The automatic gain control process 70 includes the following steps:

Step 700: Start.

Step 702: The variable-gain amplifier 500 generates an amplified signal Sa by amplifying the received signal Si according to a gain.

Step 704: The frequency response unit 508 performs a frequency response operation on the amplified signal Sa to generate the frequency response result FR.

Step 706: The power detector 504 determines power of the frequency response result FR and accordingly outputs a detection result RST.

Step 708: The gain control unit 506 adjusts the gain according to the detection result RST.

Step 710: End.

The automatic gain control process 70 is the operation of the gain control part of the automatic gain control device 50. As detailed description and modifications can be readily known by referring to above paragraphs, further description is omitted here for brevity.

In the prior art design, owing to the wide-band characteristic of a power detector, a gain control unit cannot control a variable-gain amplifier to amplify signals with different gains according to different frequency offsets of interference signals. That is, no matter whether the interference signals are present or the frequency offsets of the interference signals are different, the resulting gains are the same. In contrast to the prior art design, the present invention adds a frequency response unit to the gain control part of an automatic gain control device. The frequency response unit compensates for the wide-band characteristics of the power detector, thus allowing the detection result of the power detector to adequately reflect the frequency offsets of the interference signals. In this way, a gain of a variable-gain amplifier is adjusted according to influence of the interference signals, so as to achieve optimized performance. Therefore, with the help of the frequency response unit added to the gain control part, the present invention requires neither a narrow-band power detector nor a digital signal processing means, and is capable of achieving better performance by controlling the automatic gain control device to adjust the gain moderately according to the frequency offsets of the interference signals.

To sum up, the present invention adds a frequency response unit at a gain control part of an automatic gain control device to reflect influence imposed on a received signal due to an interference signal, and accordingly adjusts the gain to achieve better performance.

Those skilled in the art will readily observe that numerous modifications and alterations of the device and method may be made while retaining the teachings of the invention.

What is claimed is:

1. An automatic gain control device, comprising:
a variable-gain amplifier, for determining a gain according to a gain control signal and generating an amplified signal by amplifying a received signal according to the gain;
a power detector, for determining a power of a frequency response result and accordingly outputting a detection result;
a gain control unit, for outputting the gain control signal according to the detection result; and
a frequency response unit, for performing a frequency response operation on the amplified signal to generate the frequency response result.

2. The automatic gain control device of claim 1, further comprising a filter having one end coupled between the variable-gain amplifier and the power detector and the other end coupled to a back-end circuit, wherein the filter performs a filtering operation on the amplified signal before the amplified signal is output to the back-end circuit.

3. The automatic gain control device of claim 1, wherein the frequency response unit performs the frequency response operation on the amplified signal according to a frequency band of the received signal.

4. The automatic gain control device of claim 1, wherein a gain of the frequency response unit alters with frequency.

5. An automatic gain control method, comprising:
generating an amplified signal by amplifying a received signal according to a gain;
performing a frequency response operation on the amplified signal to generate a frequency response result; and
adjusting the gain according to the frequency response result.

6. The automatic gain control method of claim 5, wherein the step of adjusting the gain according to the frequency response result comprises:
detecting a power of the frequency response result; and
adjusting the gain according to the power of the frequency response result.
